(19) United States
(12) Patent Application Publication
(10) Pub. No.: US 2005/0079649 A1
(43) Pub. Date: Apr. 14, 2005

(54) ETCHANT COMPOSITION FOR SEM IMAGE ENHANCEMENT OF P-N JUNCTION CONTRAST

(76) Inventors: Shao-Kang Chang, Tao-Yuan Hsien (TW); Graham Chuang, Tao-Yuan Hsien (TW); Yi-Nan Chen, Taipei City (TW)

Correspondence Address: NORTH AMERICA INTERNATIONAL PATENT OFFICE (NAIPC), P.O. BOX 506, MERRIFIELD, VA, 22116, US

(21) Appl. No.: 10/709,054

(22) Filed: Apr. 9, 2004

(30) Foreign Application Priority Data
Oct. 13, 2003 (TW) 092128338

(51) Int. Cl. H01L 21/66; H01L 21/00

(52) U.S. Cl. 438/79

(57) ABSTRACT

An etchant composition for SEM image enhancement of P-N junction contrast. The composition comprises an NTC-1 solution mixed with an NTC-2 solution at a specific volumetric ratio. The NTC-1 solution is prepared by mixing solution “A” comprising organic acid, HF, and nitric acid with a 49% HF solution. The NTC-2 solution comprises metal ions and a strong oxidant. After the preparation of the NTC-1 and NTC-2 solutions, they are mixed together at specific volumetric ratio. Before carrying out an SEM analysis, the SEM specimen is dipped into the etchant composition.

### BACKGROUND OF INVENTION

1. Field of the Invention

The present invention relates to an etchant composition. More particularly, the present invention relates to a pretreatment etchant composition for an SEM specimen to show a contour of a P-N junction in a semiconductor substrate.

2. Description of the Prior Art

As well known in the semiconductor technology, a scanning electron microscope (SEM) is used to analyze a cross-sectional structure of an integrated circuit. For example, for a trench-capacitor DRAM, an SEM is used to observe a cross-sectional structure of a trench-capacitor. Before observing the trench-capacitor DRAM using the SEM in the prior art, the specimen is often dipped into an etching acid, generally referred to as an Oki acid or a Flou acid, to etch polysilicon of the trench-capacitor in order to form a clear contrast image in an SEM analysis process. As is well known, the Oki acid comprises a nitric acid and a 49% HF solution at a volume ratio in a range of 200:1.

In some cases, it is desired to show a contour of a P-N junction and observing a trench capacitance structure with the SEM at the same time. However, the pretreatment acid solution of the above prior art cannot make this possible. So the inventor has developed a specific etchant composition to show a clear contour of a P-N junction on the substrate of a semiconductor wafer for SEM analysis.

### SUMMARY OF INVENTION

It is the primary object of the present invention to provide a pretreatment etchant composition for an SEM specimen to show a clear contour of a P-N junction in a semiconductor substrate using an SEM.

According to the claimed invention, an etchant composition is provided. The composition comprises an NTC-1 solution mixed with an NTC-2 solution at a specific volumetric ratio. The NTC-1 solution is prepared by mixing solution “A” comprising organic acid, HF, and nitric acid with a 49% HF solution. The NTC-2 solution comprises metal ions and a strong oxidant. After the preparation of the NTC-1 and NTC-2 solutions, they are mixed together at the specific volumetric ratio.

Other objects, advantages, and novel features of the claimed invention will become more clearly and readily apparent from the following detailed description.

### BRIEF DESCRIPTION OF DRAWINGS

None

### DETAILED DESCRIPTION

A pretreatment etchant composition used to enable an SEM specimen to show a clear contour of a P-N junction in a semiconductor substrate by an SEM comprises two kinds of solutions prepared in advance at a specific volume ratio. In the following, these two solutions are referred to as an NTC-1 solution and an NTC-2 solution.

According to the preferred embodiment of the invention, the NTC-1 solution comprises a solution “A” comprising an organic acid, HF, and nitric acid with a 49% HF solution. The volume ratio of the organic acid, HF, and nitric acid in the solution “A” is in a range of 1:1:4 to 1:1:25. The solution “A” and the 49% HF solution are mixed together at a volume ratio in a range of 2:1 to 5:1. The organic acid could be formic acid, HAc, and propionic acid, and is preferably HAc. The NTC-2 solution comprises metal ions and a strong oxidant. The metal ions could be copper ions, magnesium ions, aluminum ions, calcium ions, and zinc ions, and are preferably copper ions. The NTC-2 so-lution comprises 90% hydrogen peroxide solution and copper nitrate solution with a concentration of 0.005M to 0.02M, and the volume ratio of hydrogen peroxide solution to copper nitrate solution is in a range of 2:1 to 5:1.

A pretreatment etchant composition of the present invention is used for utilizing an SEM specimen to show a clear contour of a P-N junction in a semiconductor substrate when viewing with an SEM. The etchant composition comprises the NTC-1 and NTC-2 solutions mentioned above prepared at a specific volume ratio. The specific volume ratio of the NTC-1 solution to the NTC-2 solution is in a range of 1:1 to 1:5. Before the SEM specimen analysis, the specimen is dipped into the pretreatment etchant composition, then a clear contour of a P-N junction in a semiconductor substrate could be observed in the following SEM analysis.

Those skilled in the art will readily observe that numerous modifications and alterations of the present invention may be made while retaining the teachings of the invention. Accordingly, the above disclosure should be construed as limited only by the metes and bounds of the appended claims.

1. An etchant composition comprising:
an NTC-1 solution prepared by mixing solution “A” comprising an organic acid, HF, and nitric acid with a 49% HF solution; and
an NTC-2 solution comprising metal ions and a strong oxidant;
wherein said NTC-1 solution and said NTC-2 solution are mixed together at a specific volume ratio.

2. The etchant composition according to claim 1, wherein the volume ratio of said organic acid, HF, and nitric acid in the solution “A” is in a range of 1:1:4 to 1:1:25.

3. The etchant composition according to claim 1, wherein said solution “A” and said 49% HF solution are mixed together at a volume ratio in a range of 2:1 to 5:1.

4. The etchant composition according to claim 1, wherein said organic acid comprises formic acid, HAc, and propionic acid.

5. The etchant composition according to claim 1, wherein said metal ions comprise copper ions, magnesium ions, aluminum ions, calcium ions, and zinc ions.

6. The etchant composition according to claim 1, wherein said strong oxidant comprises hydrogen peroxide, ozone, and sulfuric acid.

7. The etchant composition according to claim 1, wherein said NTC-2 solution comprises 90% hydrogen peroxide solution and copper nitrate solution with a concentration of 0.005M to 0.02M, and the volume ratio of hydrogen peroxide solution to copper nitrate solution is in a range of 2:1 to 5:1.

8. The etchant composition according to claim 1, wherein the specific volume ratio of said NTC-1 solution to said NTC-2 solution is in a range of 1:1 to 1:5.
